(19) United States
(12) Patent Application Publication
(10) Pub. No.: US 2019/0296171 A1
(43) Pub. Date: Sep. 26, 2019

(54) SOLAR CELL, SOLAR CELL MODULE AND METHOD OF MANUFACTURING THEREFOR

(71) Applicant: LG ELECTRONICS INC., Seoul (KR)

(72) Inventors: Jaewon CHANG, Seoul (KR); Youngho CHOE, Seoul (KR); Jinsung KIM, Seoul (KR)

(73) Assignee: LG ELECTRONICS INC., Seoul (KR)

(21) Appl. No.: 16/293,371

(22) Filed: Mar. 5, 2019

(30) Foreign Application Priority Data
Mar. 26, 2018 (KR) 10-2018-0034473

(51) Int. Cl. H01L 31/05; H01L 31/0216; H01L 31/0236; H01L 31/0352; H01L 31/048; H01L 31/068; H01L 31/044; H01L 31/18; H02S 40/34; H01L 31/0224; H01L 31/02

(52) U.S. Cl. CPC H01L 31/0504; H01L 31/02168; H01L 31/02363; H01L 31/035281; H01L 31/048; H01L 31/02008; H01L 31/044; H01L 31/1876; H02S 40/34; H01L 31/022425; H01L 31/0684

(57) ABSTRACT

A solar cell module can include an octagonal-shaped semiconductor substrate having a chamfer formed at each edge among at least two opposite edges of the octagonal-shaped semiconductor; and a first electrode unit formed on one surface of the octagonal-shaped semiconductor substrate, the first electrode unit including: a plurality of first sub-electrodes including first finger electrodes and a first bus bar electrode connected to ends of the first finger electrodes, and a plurality of second sub-electrodes including second finger electrodes and a second bus bar electrode connected to ends of the second finger electrodes, in which the plurality of first sub-electrodes are spaced apart from the plurality of second sub-electrodes in a first direction, and a first sub-electrode disposed adjacent to a chamfer at a first edge among the at least two opposite edges in the first direction among the plurality of first sub-electrodes, and a second sub-electrode disposed adjacent to another chamfer at a second edge among the at least two opposite edges are symmetrical in a longitudinal direction of the first and second bus bar electrodes.

### CROSS-REFERENCE TO RELATED APPLICATION

This application claims priority to and the benefit of Korean Patent Application No. 10-2018-0034473 filed on Mar. 26, 2018, in the Republic of Korea, the entire contents of which are incorporated herein by reference.

### BACKGROUND OF THE INVENTION

### Field of the Invention

Present invention relates to a solar cell for forming a fragment cell, a fragment cell module thereof and methods for forming the fragment cell module.

### Description of the Related Art

A solar cell constitutes a string to produce large electricity, and the string is packaged so that it can be used in an external environment and can be protected against moisture permeation and external impact. This packed string is called a solar cell module.

As one of methods for stringing solar cells, a shingled method has been proposed to increase the output. This shingled method refers to a method in which solar cells are partially overlapped and connected. When a solar cell is connected by a shingled method, a solar cell called a fragment cell can be used. This fragment cell is made by dividing a solar cell (hereinafter referred to as “mother cell”) produced to have a standardized size by 1/n when the solar cell is produced in the factory.

Because a fragment cell is made from a mother cell having a chamfer, the shape of the fragment cell may be different due to the chamfer of the mother cell. As a result, when composing a string with a fragment cell, there arises a problem that the fragment cells of the same shape are gathered together to form a string, or a part of the fragment cell must be discarded.

### SUMMARY OF THE INVENTION

The present invention has been derived in view of the above technical background, and it is an object of the present invention to provide a module in which all of fragment cells made of a single mother cell can be used even if the fragment cells have different shapes.

It is also an object of the present invention to connect the fragment cells so that the string made from the fragment cells can be easily repaired.

In one preferred embodiment, a solar cell includes an octagonal-shaped semiconductor substrate having a chamfer formed at an edge, a first electrode unit formed on one surface of the semiconductor substrate and having a plurality of sub electrodes including finger electrodes and a bus bar electrode connecting the ends of the finger electrodes, wherein the plurality of sub-electrodes are spaced apart from a neighboring in the first direction, and wherein the first sub-electrode firstly disposed adjacent to the chamfer in the first direction among the plurality of sub-electrodes, and a second sub-electrode disposed adjacent to the chamfer at the end are symmetrical in the longitudinal direction of the bus bar electrode.

In another preferred embodiment, a solar cell module includes a string including a cell unit in which a fragment cell is connected in a shingled manner and a plurality of cell blocks in which a plurality of the cell units are connected, a connector connecting between two adjacent cell blocks of the plurality of cell blocks, wherein the cell unit includes a first fragment cell having a long side and a short side and a second fragment cell having a chamfer at an edge.

In another embodiment, a method for manufacturing a solar cell module includes dividing a solar cell including an octagonal-shaped semiconductor substrate having a chamfer formed at an edge, a first electrode unit formed on one surface of the semiconductor substrate and having a plurality of sub electrodes including finger electrodes and a bus bar electrode connecting the ends of the finger electrodes, wherein the plurality of sub-electrodes are spaced apart from a neighboring in the first direction, and include a first sub-electrode firstly disposed adjacent to the chamfer in the first direction among the plurality of sub-electrodes and a second sub-electrode disposed adjacent to the chamfer at the end, loading a first fragment cell having a rectangular shape into a first basket and a second fragment cell having a chamfer into a second basket, connecting the first fragment cell and the second fragment cell by firstly unloading the first fragment cell and the second fragment cell from the first and the second baskets, and then positioning the second cell being arranged to partially overlap the first cell, wherein the solar cell is divided into a plurality of fragment cells aligned with scribe lines disposed between the plurality of sub-electrodes in step of the dividing a solar cell, wherein the first sub-electrode and the second sub-electrode are symmetrical in the longitudinal direction of the bus bar electrode, and wherein the second fragment cell is loaded in the second basket such that the chamfer is oriented in the same direction as another previously loaded second fragment cell in step of the loading the first and second fragment cells.

In one embodiment of the present invention, the string of fragment cells is organized in units of cell units, each cell unit comprising a hexagonal shaped cell having a rectangular fragment cell and a hexagonal fragment cell having a chamfer. Therefore, it is possible to use all of the fragment cells formed in one mother cell for the solar cell module.

In one embodiment of the invention, the string is connected by a connector to a cell block. Therefore, when the string is repaired, it is possible to selectively replace only the cell block without replacing the entire string, thereby effectively reducing repair cost and repair time.

### BRIEF DESCRIPTION OF THE DRAWINGS

FIG. 1 is a cross-sectional view of a solar cell module according to one embodiment of the present invention.

FIG. 2 illustrates a string according to one embodiment of the present invention.

FIG. 3 is a plan view of a first fragment cell and a second fragment cell.

FIG. 4 is a cross-sectional view showing interlayer structure of a fragment cell.

FIG. 5 is schematically illustrating a process of forming a first fragment cell and a second fragment cell from one mother cell.

FIGS. 6 and 7 illustrate front and rear views of the solar cell shown in FIG. 5, respectively

FIG. 8 illustrates an entire front view of the solar cell module of one embodiment.

FIGS. 9 to 11 illustrate that neighboring two cell blocks are connected in parallel by an interconnector.

FIG. 12 illustrates a physical configuration of a solar cell module according to one embodiment.

FIG. 13 illustrates an equivalent circuit of the solar cell module shown in FIG. 12.

FIGS. 14 and 15 illustrate an example of an insulating member.

FIG. 16 illustrates a method of manufacturing a solar cell module according to one embodiment of the present invention.

FIG. 17 is a schematic view showing a manufacturing method according to one embodiment of the present invention.

### DETAILED DESCRIPTION OF THE EMBODIMENTS

Reference will now be made in detail to implementations of the present invention, examples of which are illustrated in the accompanying drawings.

Present invention may, however, be implemented in many different forms and should not be construed as limited to the implementations set forth herein. Wherever possible, the same reference numbers will be used throughout the drawings to refer to the same or like parts. It will be noted that a detailed description of known arts will be omitted if it is determined that the detailed description of the known arts can obscure the implementations of the disclosure. In addition, the various implementations shown in the drawings are illustrative and may not be drawn to scale to facilitate illustration. The shape or structure can also be illustrated by simplicity.

Hereinafter, a solar cell module according to a preferred embodiment of the present invention will be described with reference to the accompanying drawings.

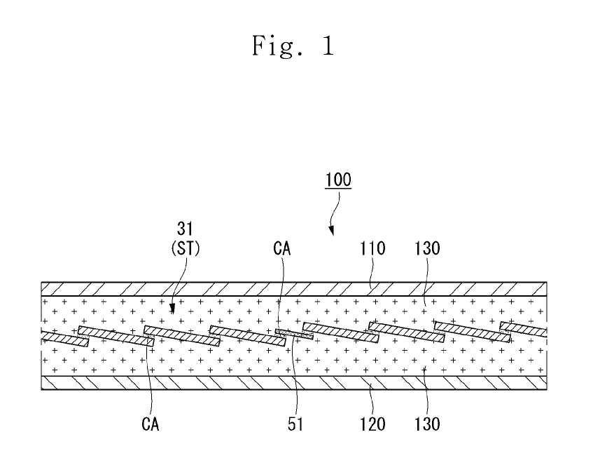

FIG. 1 is a cross-sectional view of a solar cell module according to one embodiment of the present invention. With reference to FIG. 1, the overall configuration of the solar cell module of one embodiment will be schematically described.

Referring to FIG. 1, a solar cell module 100 according to one embodiment of the present invention includes a string ST including a plurality of cell blocks 31, and a connector 51 for connecting two neighboring cell blocks among the plurality of cell blocs 31.

The connector 51 may be disposed between two neighboring cell blocks 31 and arranged to electrically and physically connect the cell blocks 31. One end of the connector 51 may be connected to the front part of the one cell block by a conductive member CA, and the other end may be connected to a rear part of the other side cell block by a conductive member CA.

Here, the cell block 31 is an array in which a plurality of fragment cells are connected in a shingled manner. In FIG. 1, for convenience of description, the overlapping of the fragment cells is omitted.

The string ST and the connector 51 are sealed by the sealing member 130 and the first cover member 110 and the second cover member 120 are disposed on the front surface and the rear surface respectively to form a solar cell module.

The first cover member 110 may be disposed on the front surface of the string ST, more precisely on the surface of the sealing member 130 disposed on the front surface of the string ST. The second cover member 120 is disposed on the rear surface of the string ST, more precisely on the surface of the sealing member 130 disposed on the rear surface of the string ST.

The first cover member 110 and the second cover member 120 may be formed of an insulating material capable of protecting the string ST from external shock, moisture, ultraviolet rays, or the like. The first cover member 110 may be made of a light-transmissive material that can transmit light, and the second cover member 120 may be made of a sheet made of a light-transmitting material, a non-light-transmitting material, or a reflective material. For example, the first cover member 110 may be formed of a glass substrate having excellent durability, excellent insulation characteristics, etc., and the second cover member 120 may be formed of a film or a sheet. In this case, the cover member 120 may have a TPT (Tedlar/PET/Tedlar) type or a polyvinylidene fluoride (PVDF) resin layer formed on at least one side of a base film, for example, polyethylene terephthalate (PET).

The sealing member 130 is physically and chemically bonded to the string ST to prevent moisture and oxygen from being introduced into the sealing member 130.

The sealing member 130 may be formed of an insulating material having light-transmitting property and adhesiveness. For example, an ethylene-vinyl acetate copolymer resin (EVA), polyvinyl butyral, a silicone resin, an ester-based resin, an olefin-based resin, or the like can be used as the sealing member 130. The sealing member 130 may be integrated with the first and second cover members 110 and 120 by a lamination process or the like to form the solar cell module 100.

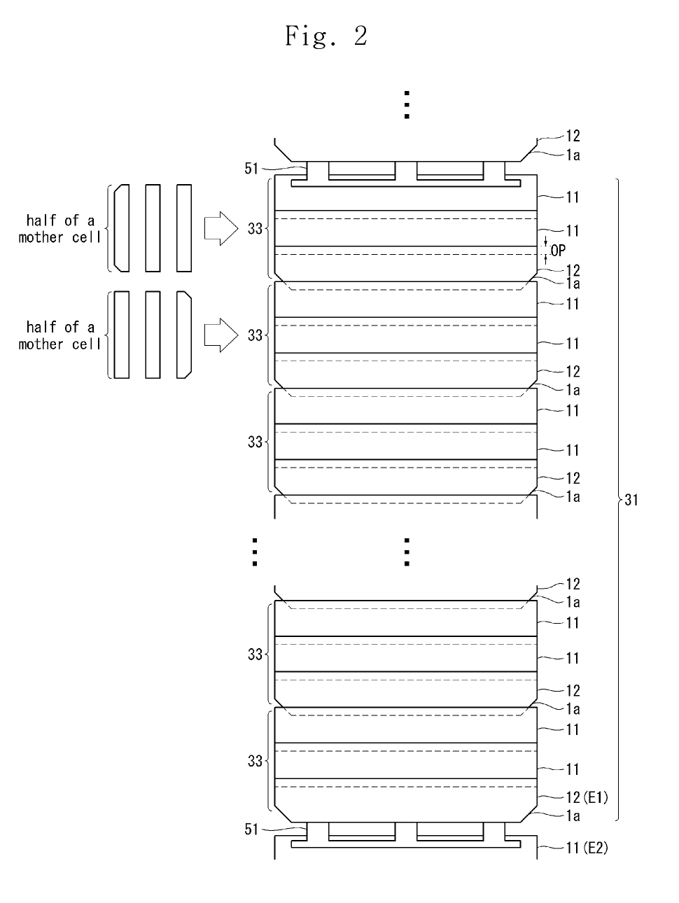

Hereinafter, a string according to one embodiment of the present invention will be described in more detail with reference to FIG. 2. FIG. 2 illustrates a string according to one embodiment of the present invention.

Referring to FIG. 2, the string ST of the one embodiment may be configured to include a plurality of fragment cells connected in series. The string ST is configured to include a plurality of cell blocks 31, and the cell blocks 31 are configured to be connected by a connector 51. And, the cell block 31 can be configured to include the cell unit 33 formed of two kinds of fragment cells having different shapes.

In one embodiment, the fragment cells are connected in a shingled connection manner, and a part of the fragment cells constitute a cell unit 33. Here, the shingled connection is a method in which a neighboring two-piece cell is partially overlapped and a conductive member (CA) is provided in an overlapped portion (hereinafter referred to as an overlapping portion OP). Here, the conductive member CA may be, for example, a conductive adhesive containing a conductive material mixed with an epoxy resin, or may be a solder such as Sn or Pb.

The cell unit 33 may include two kinds of fragment cells having different shapes. For example, the cell unit 33 may include a first fragment cell 11 having a rectangular shape and a hexagonal second fragment cell 12 having a chamfer 1a at an edge thereof.

The first fragment cell 11 and the second fragment cell 12 may be preferably formed by dividing the mother cell into 1/n pieces. Preferably, n may be six. When the mother cell is divided into six, it is easy to stably connect the fragment cell with shingled and the output loss can be minimized. Here, a mother cell refers to a solar cell that has already been manufactured including components necessary for solar power generation, such as a semiconductor substrate that forms a pn junction, an emitter, a back surface field, and an electrode. The fragment cell used in one embodiment may be formed by mechanically dividing the mother cell into 1/n pieces.

By manufacturing the string with the fragment cell as described above, it is possible to effectively reduce the manufacturing cost and minimize the output loss since there is no need to change the design of the equipment or the structure of the solar cell that has been conventionally provided for making the solar cell. The power loss of the solar cell is multiplied by the square of the current multiplied by the resistance. However, there is a current generated by the solar cell area itself in the current produced by the solar cell, and when the area of the solar cell is increased, the corresponding current is also increased, and as the area of the solar cell becomes larger, the output loss becomes larger. Therefore, if a solar cell module is formed of a fragment cell formed by dividing a mother cell, the current generated in the solar cell is reduced in proportion to the reduced area, and consequently, the output loss of the module of the solar cell can be minimized.

The cell unit 33 includes two first fragment cells 11 and one second fragment cell 12 in the case where the mother cell is divided into six. The reason for such a configuration is to improve the design of the cell unit 33. The shape of the cell unit made up of two first fragment cell 11 and one second fragment cell 12 is the same as that of the case where the mother cell is divided by half. Also, the shape of the cell unit is equal to the shape of the second fragment cell 12.

To this end, in the cell unit 33, the first fragment cell 11 and the second fragment cell 12 are arranged in the order of the first fragment cell-the first fragment cell-the second fragment cell.

The cell block 31 includes a plurality of cell units 33 configured as described above, and preferably one cell block 31 may include seven cell units 33. In one embodiment, the cell block 31 is a unit connected by the connector 51, and the string ST is formed by connecting a plurality of cell blocks 31 by the connector 51. The reason why the string ST is divided into the plurality of cell blocks 31 is that the stress applied to the string ST is relieved and the repair is easy when the string ST is abnormal.

In the case of a string (hereinafter, referred to as a comparative example) in which the entire string is connected in a shingled manner, as in the prior art, without connection by the connector 51 as in the present embodiment, the stress applied to the string is (y-axis direction of the drawing), it is concentrated in the relatively weak portion of the connected portion (overlapping portion) in the shingled manner, resulting in physical destruction. In contrast, in the present embodiment, since the connector 51 is disposed in the middle of the string, the stress propagating in the longitudinal direction of the string ST is absorbed by the connector 51, so that the entire string can be protected. In a case where a defect occurs in a part of the string, for example, a part of the string, the entire string needs to be replaced in the case of the comparative example. However, in present embodiment, it is easy to repair and the cost can be effectively reduced. Also, such connection by the connector 51 is convenient for electrically connecting a plurality of strings. For example, if the cell block 31 is to be connected in parallel to a cell block of a neighboring string, in this embodiment, the two neighboring connectors are connected in parallel so that the cell blocks can be connected in parallel.

The connector 51 electrically connects the end fragment cell E1 disposed at one end of the cell block 31 and the end fragment cell E2 disposed at the head of another cell block. In one example, one end of the connector 51 may be connected to the front surface of the end fragment cell E1 and the other end may be connected to the rear surface of the end fragment cell E2 to connect the cell blocks 31 in series.

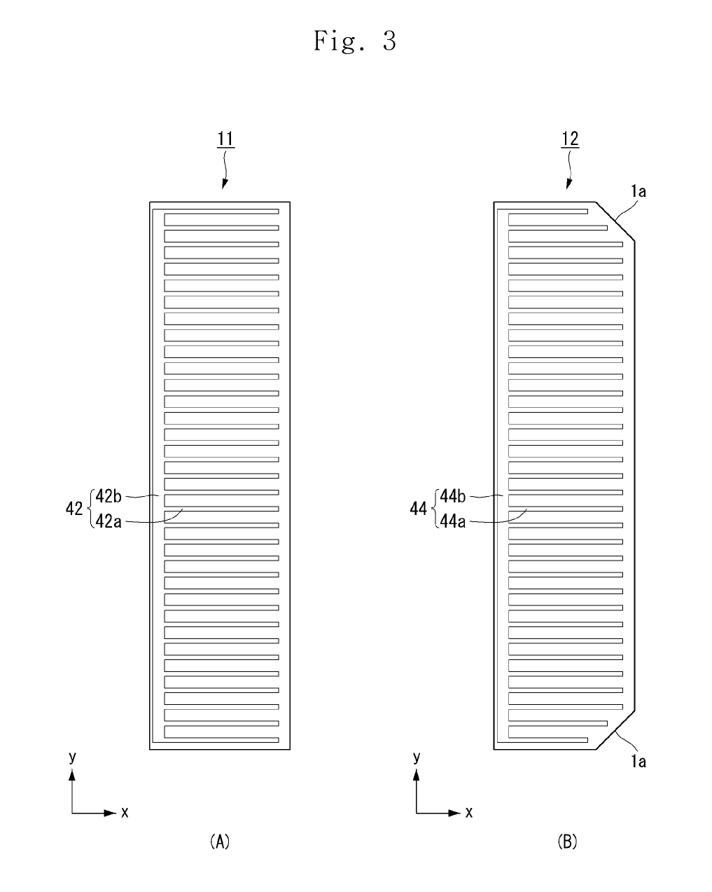

Hereinafter, the first and second segment cells will be described in detail with reference to FIG. 3. FIG. 3 illustrates a plan view of a first fragment cell and a second fragment cell, wherein (A) shows a first fragment cell, (B) shows a second fragment cell, and in FIG. 3, for example, the rear view is shown as an example.

The first fragment cell 11 has a rectangular shape having a shorter side 11a in the first direction (x-axis direction in the drawing) and a longer side 11b in the second direction (y-axis direction in the drawing). As will be described later, the first fragment cell 11 may be formed by dividing a mother cell into a plurality of fragment cells. The aspect ratio (short side/long side) of the long side 11b and the short side 11a is preferably 1/2 to 1/12, more preferably 1/6.

A first electrode (42) is disposed on the rear surface of the first fragment cell 11. In one preferred example, the first electrode 42 includes a plurality of first finger electrodes 42a and a first bus bar electrode 42b. The plurality of first finger electrodes 42a are spaced apart from the neighboring ones in the second direction (y-axis direction in the figure) and the first bus bar electrode 42b extends in a second direction while connecting ends of the plurality of first finger electrodes 42a.

The plurality of first finger electrodes 42a extend from one short side of the semiconductor substrate toward the other short side in the first direction (x-axis direction in the drawing), and are formed to be spaced apart from the neighboring ones in the second direction.

The first bus bar electrode 42b is disposed to be long along one long side and adjacent to one long side rather than the other long side to connect the ends of the plurality of first finger electrodes 42a. The first bus bar electrode 42b not only electrically connects the plurality of first finger electrodes 42a, but also functions as a pad. Here, the pad refers to an interface that allows adjacent fragment cells to be electrically and physically connected when neighboring fragment cells are connected in a shingled manner.

Therefore, in a preferred form, it is preferable that the line width of the first bus bar electrode 42b is larger than the line width of the first finger electrode 42a in order to improve the physical and electrical connection. However, for reference, in the drawing, the entire line width of the first bus bar electrode 42b is formed larger than the line width of the first finger electrode 42a. Alternatively, however, the first bus bar electrode 42b may have the same line width as the first finger electrode 42a, or the pad may be partially formed on the first bus bar electrode 42b so as to have a line width that is thicker than the line width of the first bus bar electrode 42b.

According to this structure, when the two fragment cells are connected by the shingled connection method, the first bus bar electrode 42b of one fragment cell is arranged along the overlap portion, A pad (or other bus bar electrode) of the other fragment cell is disposed to overlap the first bus bar electrode 42b of one fragment cell so that the two fragment cells can be electrically and physically connected by a conductive member (CA).

The second fragment cell 12 has substantially the same configuration as the first fragment cell 11, that is, all of the elements constituting the cell (for example, the semiconductor substrate or the emitter, pn junction, etc.) are the same and differ only in shape.

The second fragment cell 12 is formed in such a manner that a part of the corner where the long side 12b and the short side 12a meet each other has the chamfer 1a so that the second fragment cell 12 has a hexagonal shape which is almost rectangular.

In the second fragment cell 12, it is preferable that the first bus bar electrode 42b is disposed adjacent to the other long side 12b facing the one side 12a where the chamfer 1a is formed. When connecting a plurality of fragment cells in a shingled connection manner, it is convenient to connect the fragment cells in order that the rear part of the new fragment cell should be arranged so as to form an overlap with the front part of the preceding fragment cell. In the present embodiment, the second fragment cell 12 constitutes the cell unit 33 together with the first fragment cell 11. And the second fragment cell 12 in the cell unit 33 is arranged in the last order so that the cell unit 33 can have the same shape as the second cell 12. Therefore, it is preferable that the second bus bar electrode 44b functioning as a pad on the rear surface of the second fragment cell 12 is arranged to be adjacent to the other long side 12b.

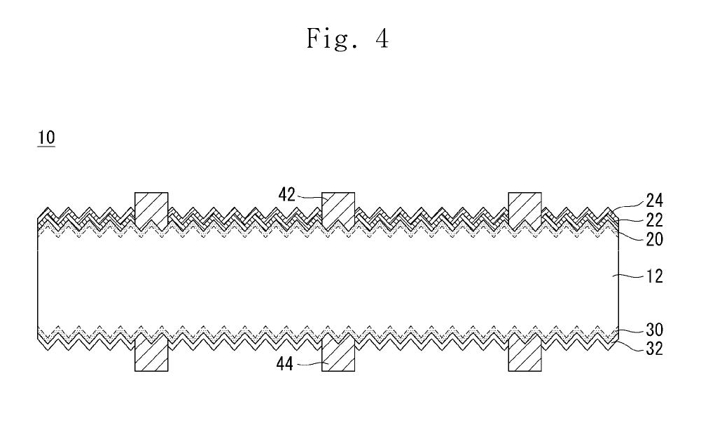

Since the first and second fragment cells are made from the mother cell having the configuration as shown in FIG. 4, it is possible to receive a light from a front side and back side. That is, the first and second fragment cells are a double-sided light receiving solar cell.

The solar cell 10 includes a semiconductor substrate 12, conductive regions 20 and 30 formed on or in the semiconductor substrate 12 and electrodes 42 and 44 connected to the conductive regions 20 and 30 and is a bifacial solar cell. In addition, the solar cell 10 of the present embodiment may be a crystalline solar cell based on the semiconductor substrate 12. For example, the conductive type regions 20 and 30 include a first conductive type region 20 and a second conductive type region 30 having different conductivity types, and the electrodes 42 and 44 may include a first electrode 42 connected to the region 20 and a second electrode 44 connected to the second conductive region 30.

The semiconductor substrate 12 includes a first or a second conductivity type dopant doped with a relatively low doping concentration, and may be any one of a crystal type, for example, a single crystal silicon or a polycrystalline silicon substrate. At this time, at least one of the front surface and the rear surface of the semiconductor substrate 12 may have a texturing structure or an antireflection structure having a concavo-convex shape such as a pyramid to minimize reflection. In the drawing, concavities and convexities are formed on both of the front and rear surfaces in accordance with the bifacial solar cell.

The conductive regions 20 and 30 includes a first conductive type region 20 located on one side (e.g., front side) of the semiconductor substrate 12 and having a first conductive type, and a second conductive type region 30 located on the other side (e.g., the other side) of the first conductive type and having the second conductive type. The conductive regions 20 and 30 may have a conductivity type different from that of the semiconductor substrate or may have a higher doping concentration than the semiconductor substrate 12. In the present embodiment, the first and second conductivity type regions 20 and 30 are constituted by a doped region constituting a part of the semiconductor substrate 12, so that the junction characteristics with the semiconductor substrate 12 can be improved. At this time, the first conductive type region 20 or the second conductive type region 30 may have a homogeneous structure, a selective structure, or a local structure.

However, the present invention is not limited thereto, and at least one of the first and second conductivity type regions 20 and 30 may be formed separately from the semiconductor substrate 12 on the semiconductor substrate 12. In this case, a semiconductor layer (for example, an amorphous semiconductor layer, an amorphous semiconductor layer, or the like) having a crystal structure different from that of the semiconductor substrate 12 is formed so that the first or second conductivity type regions 20 and 30 can be easily formed on the semiconductor substrate 12, a microcrystalline semiconductor layer, or a polycrystalline semiconductor layer.

Of the first and second conductivity type regions 20 and 30, one region having a conductivity type different from that of the semiconductor substrate 12 constitutes at least a part of the emitter region. The other of the first and second conductivity type regions 20 and 30 having the same conductivity type as the semiconductor substrate 12 constitutes at least a part of a surface field region. For example, in the present embodiment, the semiconductor substrate 12 and the second conductivity type region 30 may have a second conductivity type and an n type, and the first conductivity type region 20 may have a p type. Then, the semiconductor substrate 12 and the first conductivity type region 20 form a pn junction. When the pn junction is irradiated with light, the electrons generated by the photoelectric effect move toward the rear side of the semiconductor substrate 12 and are collected by the second electrode 44, and the holes move toward the front side of the semiconductor substrate 12 1 electrode 42. Thus, electric energy is generated. Then, holes having a slower moving speed than electrons may move to the front surface of the semiconductor substrate 12, rather than the rear surface thereof, thereby improving the efficiency. However, the present invention is not limited thereto, and it is also possible that the semiconductor substrate 14 and the second conductivity type region 30 have a p-type and the first conductivity type region 20 has an n-type. The semiconductor substrate 12 may have the same conductivity type as that of the second conductivity type region 30 and opposite to the first conductivity type region 20.

The first or second conductivity type dopant may be n-type or p-type. As the p-type dopant, a group III element such as boron (B), aluminum (Al), gallium (Ga), indium (In) In the case of the n-type, Group V elements such as phosphorus (P), arsenic (As), bismuth (Bi) and antimony (Sb) can be used. For example, the p-type dopant may be boron (B) and the n-type dopant may be phosphorus (P).

A first passivation layer 22 and/or a first insulating layer 22 are formed on the front surface of the semiconductor substrate 12 (more precisely, on the first conductive type region 20 formed on the front surface of the semiconductor substrate 12) or antireflection layer 24 may be positioned (e.g., in contact). A second passivation layer 32, which is a second insulating layer, is formed on (e.g., in contact) the rear surface (more precisely on the second conductive type region 30 formed on the rear surface of the semiconductor substrate 12) of the semiconductor substrate 12. The first passivation layer 22, the antireflection layer 24, and the second passivation layer 32 may be formed of various insulating materials. For example, the first passivation layer 22, the antireflection layer 24, or the second passivation layer 32 may be a silicon nitride layer, a silicon nitride layer including hydrogen, a silicon oxide layer, a silicon oxynitride layer, an aluminum oxide layer, a silicon carbide layer, ZnS, TiO2, and CeO2, or a multilayer structure in which two or more layers are combined. However, the present invention is not limited thereto.

A first electrode 42 is electrically connected to the first conductive type region 20 via the opening passing the first insulating layer and a second electrode 44 is electrically connected to the second conductive type region 30 via the opening passing the second insulating layer. The first and second electrodes 42 and 44 are formed of various conductive materials (e.g., metal) and may have various shapes.

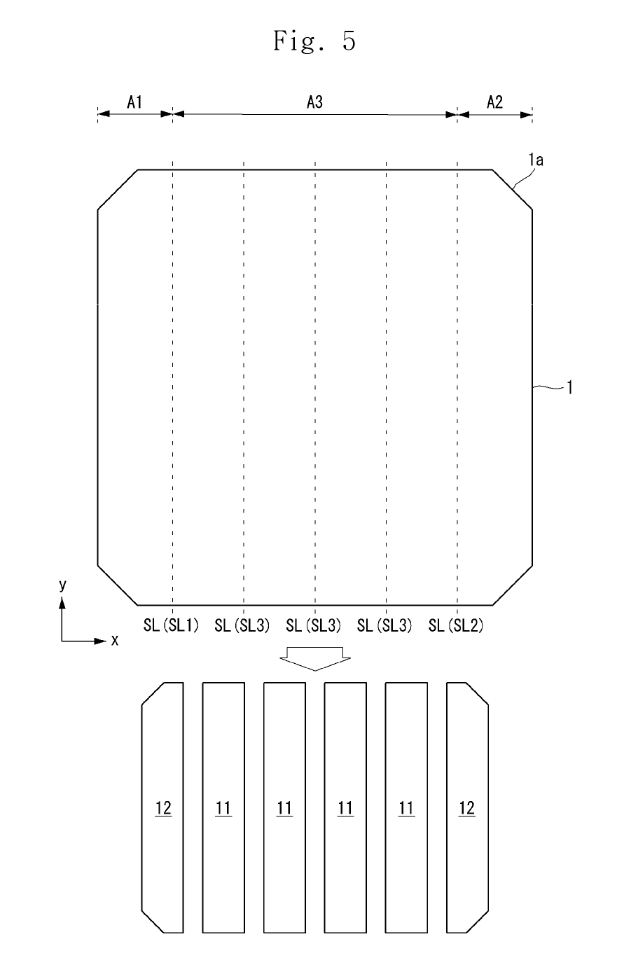

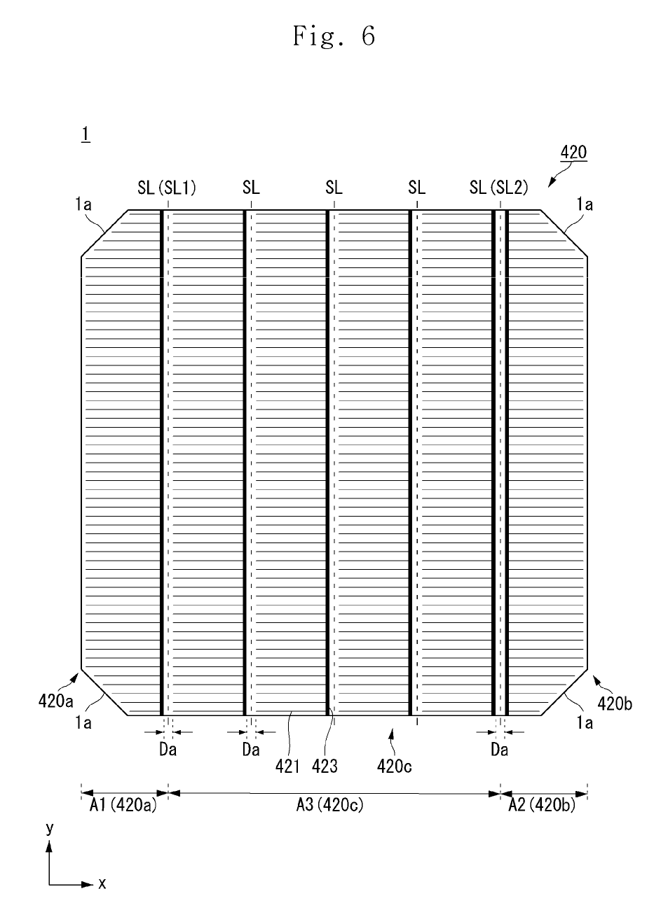

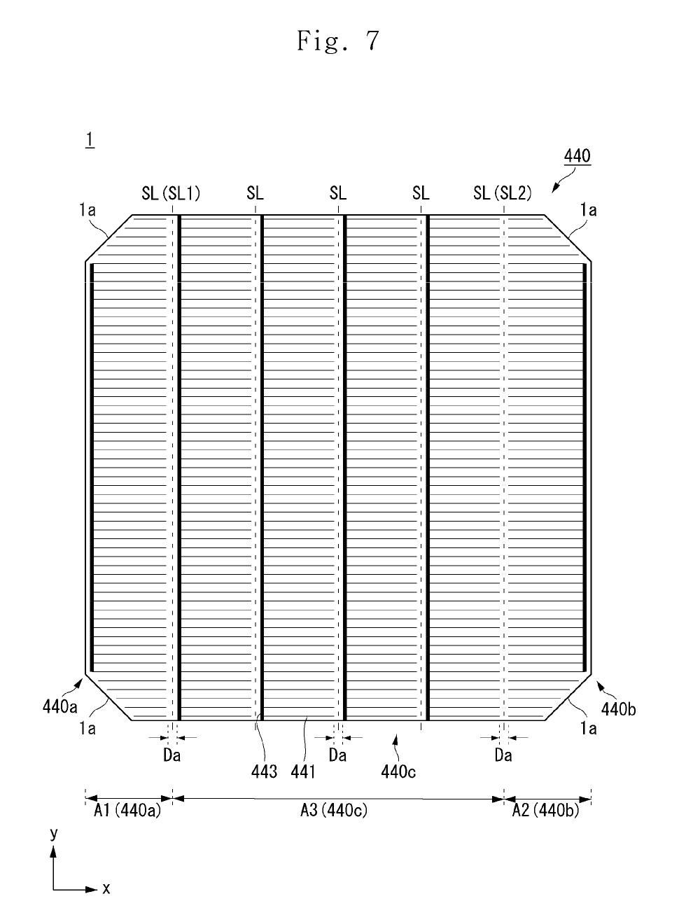

As described above, the first fragment cell and the fragment second cell, which are used in one embodiment, can be formed by dividing the mother cell into a plurality of fragment cells, which will be described in detail with reference to FIGS. 5 to 7. FIG. 5 is schematically illustrating a process of forming a first fragment cell and a second fragment cell from one mother cell. FIGS. 6 and 7 illustrate front and rear views of the solar cell shown in FIG. 5, respectively

In this embodiment, the mother cell 1 is preferably a solar cell having a substantially octagonal shape in which a chamfer 1a is formed at each corner. The mother cell 1 has a substantially square shape in which the long side in the first direction (x-axis direction in the figure) and the long side in the second direction (y-axis direction in the drawing) are substantially the same, thereby forming an octagonal shape as a whole.

The mother cell 1 is made from a circular ingot (monocrystalline), and is made into a substantially octagonal shape having a chamfer 1a at an edge so as to have the widest possible area.

The mother cell 1 having the shape as described above is divided into a plural in accordance with scribing lines SL arranged so as to be spaced apart from a neighboring one in the first direction (x-axis direction in the figure). The scribing line SL is elongated from one long side to the other long side in parallel with the long side of the first direction or the second direction. In the drawing, it is exemplified that the scribing lines SL are arranged side by side in the second direction (y-axis direction in the figure).

The mother cell 1 is divided into a plurality of pieces in accordance with the scribing line (SL) in consideration of various parameters of the manufacturing process such as the size of the mother cell, the output of the piece cell, and the number of the piece cells constituting the string. Preferably, the mother cell 1 can be divided into 2 to 12. In the drawing, it is exemplified that the mother cell 1 is divided into 6 fragment cells in accordance with the cell unit 33. If the mother cell 1 is divided into 2, the damage to the mother cell (for example, thermal shock caused by the laser) can be minimized. If the mother cell 1 is divided over 12, it is difficult to connect the fragment cells in a shingled manner because the size of the fragment cells is small.

The mother cell 1 can be largely divided into the first to third regions A1 to A3. The first region A1 is between the one long side and the first scribing line SL1 and the second region A2 is between the second scribing line SL2 and the other long side. The first and second regions A1 and A2 are regions including the chamfer 1a, the first and second regions A1 and A2 become the two second fragment cell 12 having a substantially hexagonal shape including the chamfer after scribing. The third region A3 has a rectangular shape between the first scribing line SL1 and the second scribing line SL2. This third area A3 is divided into four pieces corresponding to the third scribe line SL3 and becomes four first fragment cells 11 having a rectangular shape.

As described above, in the present embodiment, the string ST is constituted by a minimum unit of the cell unit 33. In one example, the cell unit 33 includes two first fragment cell 11 and one second fragment cell 12. Therefore, when the mother cell 1 is divided into six pieces, one mother cell 1 can constitute two cell units 33, and all the cell pieces divided in the mother cell 1 can be divided into a string.

The first electrode unit 420 constituting the first electrode 42 is formed on one side of the mother cell 1, for example, on the rear side thereof. The first electrode unit 420 is configured to include a plurality of sub electrodes spaced apart from each other by a predetermined distance Da adjacent to the sub electrode in the first direction. Each of the sub electrodes is configured to include finger electrodes 421 and a bus bar electrode 423 connecting one end of the finger electrodes.

In the present embodiment, the plurality of sub-electrodes may include first to third sub-electrodes 420a to 420c. The first sub-electrode 420a may be disposed in the first region A1, The second sub-electrode 420b may be disposed in the second region A2 and the third sub-electrode 420c may be disposed in the third region A3. One set of the first sub-electrode 420a and one set of the second sub-electrodes 420b are disposed in the first and second regions A1 and A2 while a plurality set of the third sub-electrode 420c is disposed in the third region A3.

In the first to third sub-electrodes 420a to 420c, the finger electrodes 421 are disposed at regular intervals from the neighboring ones in the second direction (y-axis direction in the figure). The bus bar electrode 423 is elongated in a second direction (for example, along the scribe line SL) and is formed to connect one end of the finger electrode 421. The entire shape of the bus bar electrode 423 may be line-shaped and may have a line width greater than the finger electrode 421 in order to function as a pad.

The bus bar electrode 423 is formed on one end (for example, the left end) of the finger electrode 421 so as to have the same shape as all the third sub-electrodes 420c, or the other end (for example, the right end). In the drawing, the bus bar electrode 423 is disposed to connect the other end of the finger electrode 421 like the first sub-electrode 420a. Accordingly, when the mother cell 10 is divided into a plurality of fragment cells aligned with the scribe line SL, the plurality of third sub-electrodes 420c may have the same shape in each fragment cell.

The bus bar electrode 423 in the first sub-electrode 420a may be disposed to connect the other end of the finger electrode 421 in the same manner as the bus bar electrode of the third sub-electrode 420c.

On the contrary, in the second sub-electrode 420b, the bus bar electrode 423 is preferably disposed to connect the finger electrode 421 in a direction opposite to the bus bar electrode of the first sub-electrode 420a. The bus bar electrode 423 of the second sub-electrode 420b may be disposed to connect one end (left end) of the finger electrode 421.

According to this, the first sub-electrode 420a and the second sub-electrode 420b are formed to have a symmetrical shape with respect to the scribing line SL. Since the first sub-electrode 420a and the second sub-electrode 420b have such a symmetrical shape, when fabricating the solar cell module, all of the fragment cells made from one mother cell are used to form the string. Thus the manufacturing cost can be effectively reduced.

In the above description, the bus bar electrode 423 constituting the first electrode unit 420 is configured to have a line shape, but the present invention is not limited thereto. In one embodiment, one end of the finger electrode may be connected by a connection electrode having the same line width as the finger electrode, and the pad may have a shape in which a pad having a partially widened width is formed on the connection electrode.

Meanwhile, FIG. 7 illustrates an embodiment of a second electrode unit formed on a surface opposite to the surface on which the first electrode unit is formed.

Similarly to the first electrode unit 420, the second electrode unit 440 may include a plurality of sub-electrodes spaced apart from each other by a predetermined distance Da from the neighboring in the first direction. Each of the plurality of sub-electrodes may include a plurality of finger electrodes 441 and a bus bar electrode 443 connecting one end of the plurality of finger electrodes 441.

The configuration of the finger electrode 441 and the bus bar electrode 443 is substantially the same as that of the first electrode unit, and a detailed description thereof will be omitted.

Compared with the first electrode unit 420, the second electrode unit 440 is different from the first electrode unit 420 in that the bus bar electrode 443 is formed in the first to third areas A1 to A3, But in the opposite direction. For example, if the bus bar electrode 423 is arranged to connect the right end of the finger electrode 421 in the first sub-electrode 420a in the first region A1, In the first auxiliary electrode 440a, the bus bar electrode 443 is arranged to connect the left end of the finger electrode 441.

Thus, when the solar cell 10 is divided into a plurality of fragment cells along the scribe line SL, the bus bar electrodes 423 and 443 functioning as pads are positioned in opposite directions on different surfaces.

In the present invention, the fragment cells are connected in a shingled manner, and the shingled method is a method of partially overlapping the two fragment cells in the overlapping portion. Accordingly, when the pads disposed on the front side and the pads disposed on the rear side are disposed to be staggered, the pads of the two fragment cells are disposed to face each other at the overlapping portion without changing a position.

In the above description, the configuration of the solar cell module according to one embodiment in which the mother cell 1 is divided into two kinds of first fragment cells 11 and second fragment cells 12 having different shapes, The configuration of the mother cell 1 has been described, but the present invention is not limited thereto. In one example, the mother cell 1 may be divided into fragment cells of the same shape. The mother cell 1 may be divided into two pieces along the scribe line passing through the center of the mother cell 1, in which case the two divided pieces are in the same hexagonal shape as the second fragment cell 12. Also in this case, the cell unit 33 can be composed of one fragment cell, so that the cell block 31 is composed of seven fragment cells, and the cell block 31 can be configured to be connected by the connector 51.

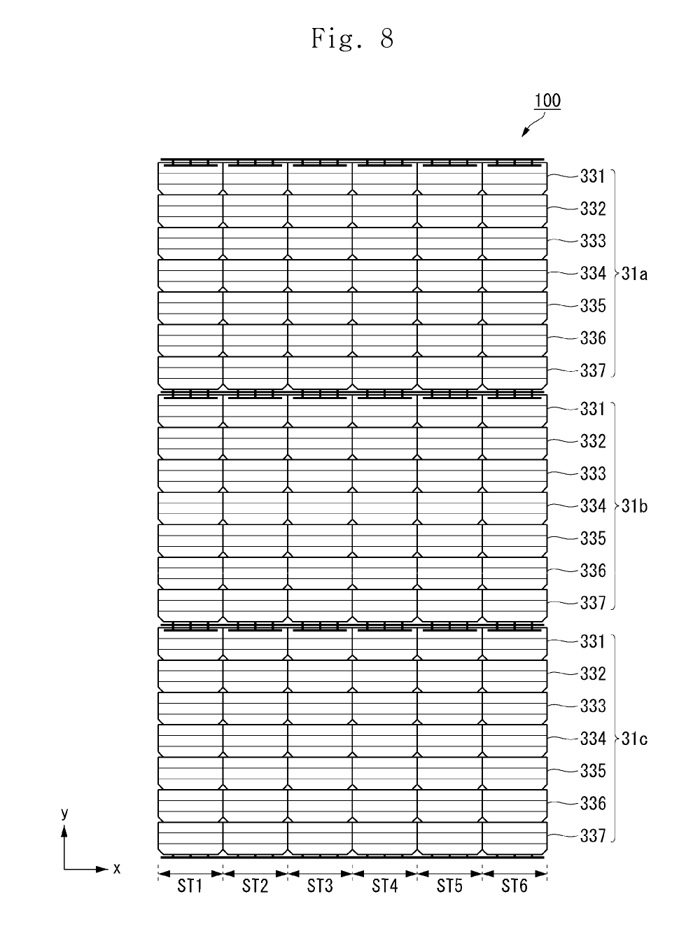

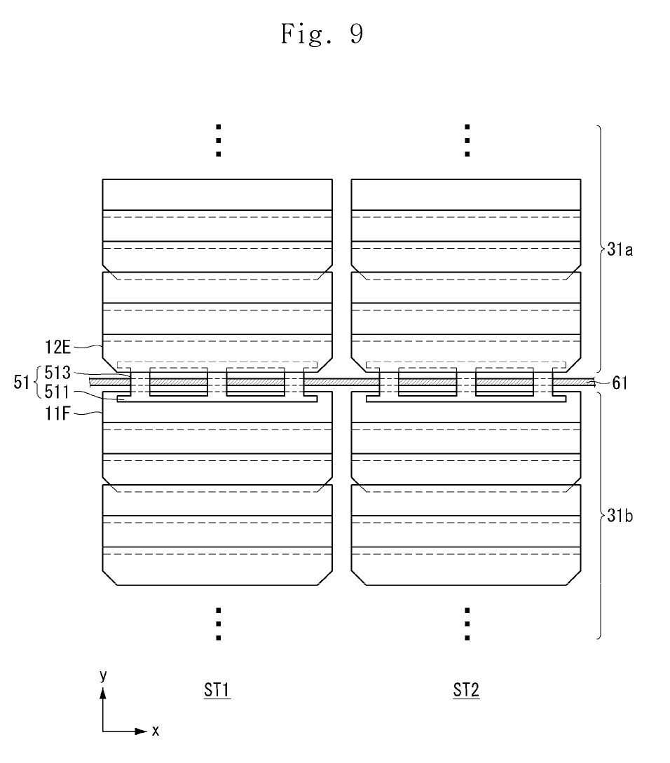

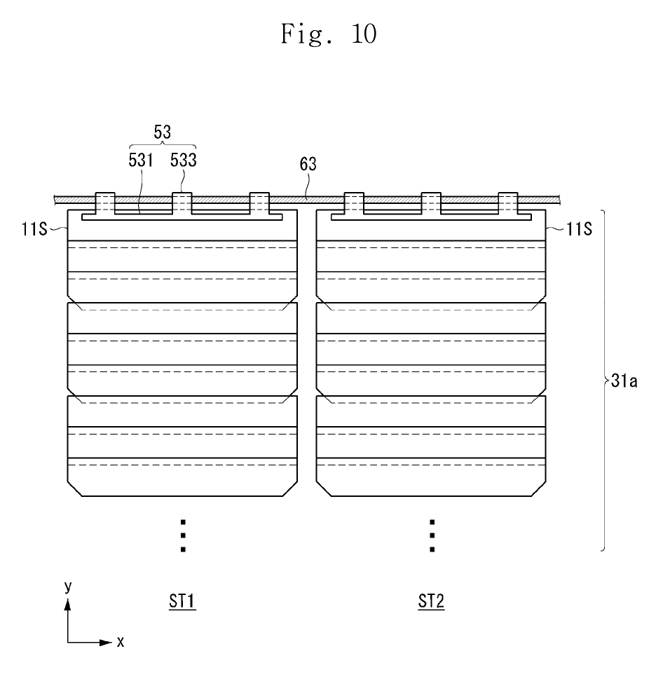

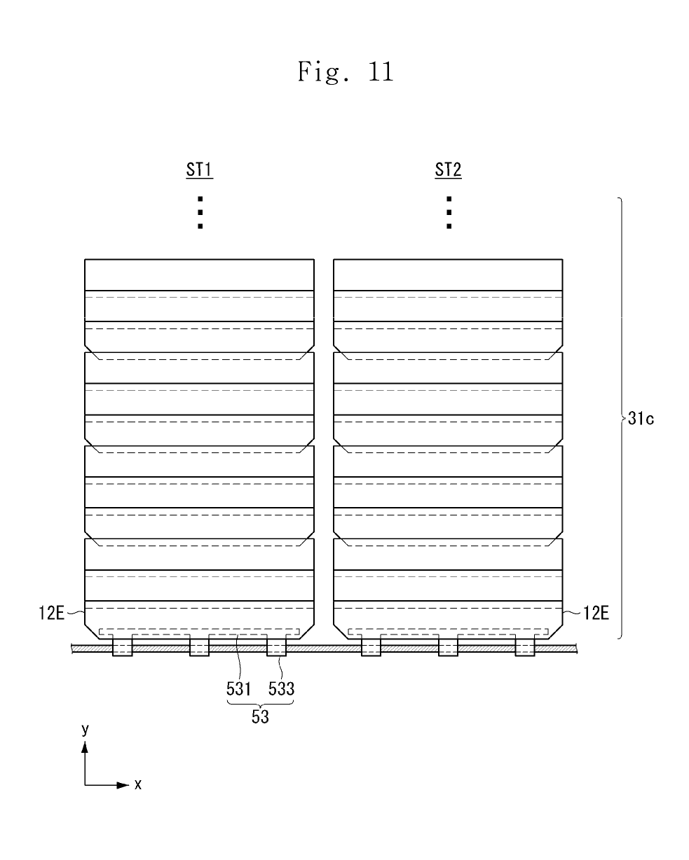

Hereinafter, how the strings are connected to each other in the solar cell module will be described with reference to FIGS. 8 to 11. FIG. 8 illustrates an entire front view of the solar cell module of one embodiment. FIGS. 9 to 11 illustrate that neighboring two cell blocks are connected in parallel by an interconnector.

Referring to FIGS. 8 to 11, the solar cell module 100 of the present embodiment is configured to include a plurality of strings ST1 to ST6 connected in parallel. As described above, each of the strings ST1 to ST6 includes the cell block 31 with the cell unit 33 as a minimum unit, and the cell block 31 is connected to the neighboring cell block 31 by the connector 51 in series. Preferably, in each of the strings ST1 to ST6, the seven cell units 331 to 337 constitute one cell block 31a, 31b and 31c, and the three cell blocks 31a to 31c are combined to form one string.

In the cell unit 33, each fragment cell is electrically connected in series with the neighboring one in a shingled manner in the second direction (y-axis direction in the figure) (fragment cell includes a first electrode and a second electrode disposed on the rear surface and the front surface, respectively, and the first electrode and the second electrode of the neighboring two fragment cell are connected by the shingled connection), and the cell blocks are electrically connected in series by the connector 51. Therefore, the all of fragment cells in each string ST1 to ST6 are connected in series.

The connector 51 may be configured to include a pair of first portions 511 disposed in parallel and a plurality of second portions 513 connecting the first portions 511. The first portion 511 has a thin strip shape and is formed long in the first direction (x-axis direction in the figure). The second portion 513 has a line width larger than the first portion and extends in a second direction (the y-axis direction in the drawing), connects a pair of the first portion 511, and the second portion 513 are spaced apart from the neighboring to effectively disperse a stress to the string.

One of the first portion 511 is attached to the front surface of the second fragment cell 12E disposed at the end of the first cell block 31 among the two adjacent cell blocks 31 and 32 in the second direction, and the other of the first portion 511 can be attached to the back surface of the first cell block 11F disposed at the beginning of the second cell block 32. More precisely, the first portion 511 attached to the front surface of the second fragment cell 12E is connected to the pad disposed on one side of the second fragment cell 12E or the second bus bar electrode 44b, and the first portion 511 attached to the rear surface of the first cell block 11F is connected to the first bus bar electrode 42b of the first electrode 42, or a pad and bonded by a conductive member (CA). Thus, the neighboring two cell blocks 31 and 32 can be connected in series.

In each of the strings ST1 to ST6, each string may be further configured to include an edge connector 53 disposed at the beginning and end of the string. For example, the first fragment cell 11S may be disposed at the beginning of each string ST1 to ST6, and the second fragment cell 12E may be disposed at the end.

The edge connector 53 has a line portion 531 formed to be elongated in the first direction (x-axis direction in the figure) and a protrusion portion 531 protruded in the second direction (y-axis direction in the drawing) at the line portion 531. Here, the edge connector 53 disposed in the first cell 11S is attached to either the front or rear surface of the first fragment cell 11S and the edge connector connected to the second fragment cell 12E 53 may be attached to the opposite side of the second fragment cell 12E.

Preferably, the line portion 531 of the edge connector 53 in the first fragment cell 11S and the second fragment cell 12E faces to a pad or a first (or second) bus bar electrode and may be electrically and physically connected by a conductive member (CA).

The connector 51 and the edge connector 53 disposed in each string can be electrically connected to each other by the first and second inter-connecters 61 and 63 in the first direction.

The first inter-connecter 61 connects the connectors for connecting the cell block in each string ST1 to ST6 in parallel with the neighboring string in the middle of the string. The first inter-connecter 61 has a line shape and is arranged to traverse from the first string ST1 to the last sixth string ST6 and is physically bonded to the second portion 513 of the connector 51. In one preferred example, the physical bonding may be accomplished by soldering in which solder is used to bond the base materials in a preferred example, however, the present invention is not limited thereto, and various known bonding methods can be used.

The second inter-connecter 63 is disposed at the end of the string side by side with the first inter-connecter 61 in parallel and is physically bonded to the edge connector 53 connected to the end of the string. Since the second inter-connecter 63 has substantially the same physical structure as the first inter-connecter 63, detailed description thereof will be omitted. More precisely, the second inter-connecter 63 can be disposed so as to cross the protruding portion 533 of the edge connector 53.

With this configuration, each of the strings ST1 to ST6 can be connected in series and connected in parallel for each cell block of each string. According to such a configuration, since a bypass path is formed even if a part of the string is shut down, a part of the string, more precisely, the normal operation can be performed for each cell block.

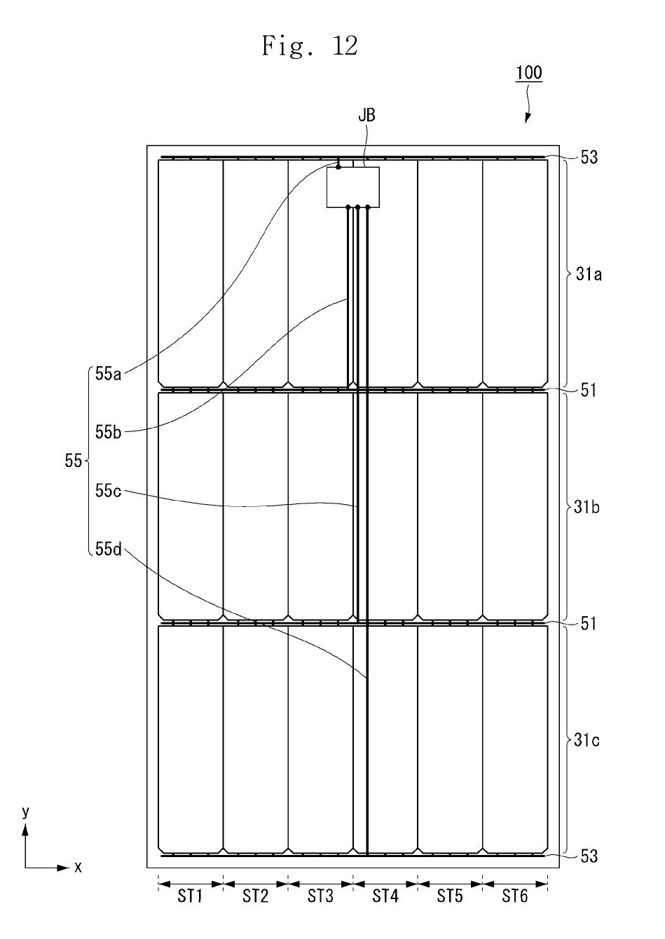

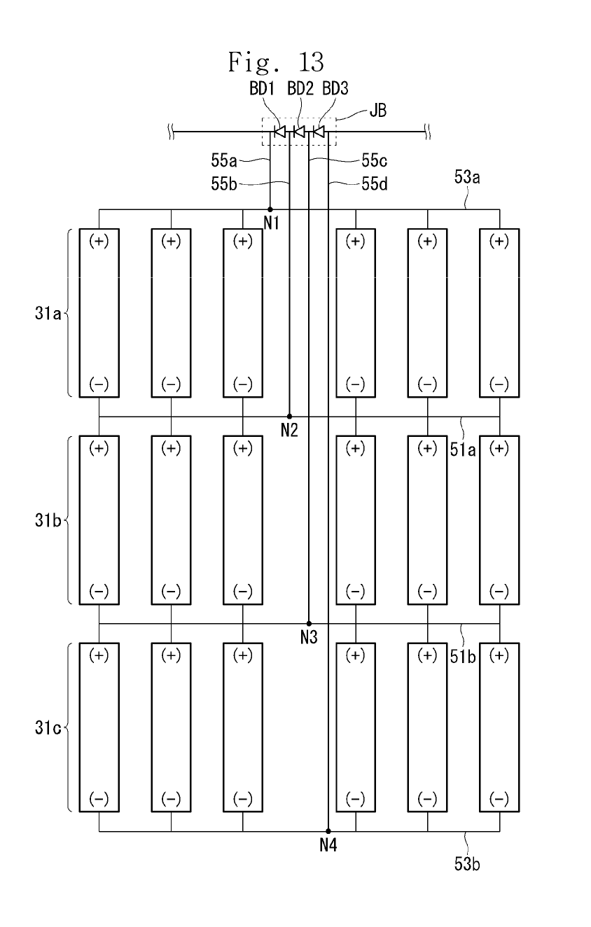

Hereinafter, the circuit configuration of the solar cell module according to the present embodiment will be described with reference to FIGS. 12 and 13. FIG. 12 illustrates a physical configuration of a solar cell module according to one embodiment and FIG. 13 illustrates an equivalent circuit of the solar cell module shown in FIG. 12.

Referring to FIGS. 12 and 13, the solar cell module 100 of this embodiment includes a junction box (JB) disposed on the rear surface of the string and including a bypass diode BD. In one example, the bypass diode BD is configured to include the first to third bypass diodes BD1 through BD3 connected in series.

As shown in the figs, each of the strings ST1 to ST6 is configured to include first to third cell blocks 31a to 31c. The first cell blocks 31a disposed in the strings ST1 to ST6 are configured to be connected in parallel by the first and second inter-connectors 51 and 53. The second cell blocks 32b are connected in parallel by a pair of second inter-connectors 51 and the third cell blocks 31c are configured to be connected in parallel by the first connector 51 and the second interconnectors 53.

The solar cell module 100 of this embodiment is further configured to include bushing connectors 55a to 55d arranged on the rear surface of the module. These bushing connectors 55a to 55d connect between the interconnectors 51 and 53 and the bypass diodes BD1 to B3. According to this, even if a reverse bias occurs in a part of the string, the reverse bias can be bypassed toward the bypass diode, thereby preventing the string from being turned off.

The bushing connectors 55a to 55d may be formed to have a long line shape in the second direction (the y-axis direction in the drawing), and may be arranged in parallel with other bushing connectors. In the figure, it is illustrated that the junction box JB is disposed close to one side of the string and far from the other side so that the first bushing connector 55a is shortest and the fourth bushing connector 55d is longest. However, the present invention is not limited thereto, and the junction box JB can be changed in its position in accordance with the selection, and the length of the bushing connector can also be adjusted.

The first bushing connector 55a electrically connects the second inter-connecter 53a commonly connected to one end of the first cell blocks 31a with the positive polarity of the first bypass diode BD1. The first bushing connector 55a may be connected to the second interconnector 53b via the first node N1. The first bushing connector 55a may be soldered to the second interconnect 53a or may be connected by a conductive member (CA), but is preferably soldered for convenient operation.

One end of the second bushing connector 55b is connected to a second node N2 commonly connected to the first cell block 31a and the second cell block 31b, that is, the first inter-connector 51a disposed between a first cell block 31a and a second cell block 31b. And the other side of the second bushing connector 55b is commonly connected to the negative polarity of the first bypass diode B1 and the positive polarity of the second bypass diode to form a bypass path of the first cell block 31a.

One end of the third bushing connector 55c is connected to a third node N3 commonly connected to the second cell block 31b and the third cell block 31c, that is, the inter-connector 51a disposed between a first cell block 31a and a second cell block 31b. And the other side of the third bushing connector 55c is commonly connected to the negative polarity of the second bypass diode B2 and the positive polarity of the third bypass diode BD3 to form a bypass path of the third cell block 31c.

In this embodiment, the connector, the inter-connector, and the bushing connector are preferably formed of a metal core layer and a ribbon of a solder material (for example, Sn, Pb) which is coated on the core layer. The present invention is not limited thereto, and various ones known can be used.

By this, the solar cell modules of one embodiment can be connected in series for each string, and can be connected in parallel for each cell block. Accordingly, even if a reverse bias is generated in one part of the string, the cell block bypasses the reverse bias through the bypass path, so that the string itself can be prevented from being turned off by reverse bias.

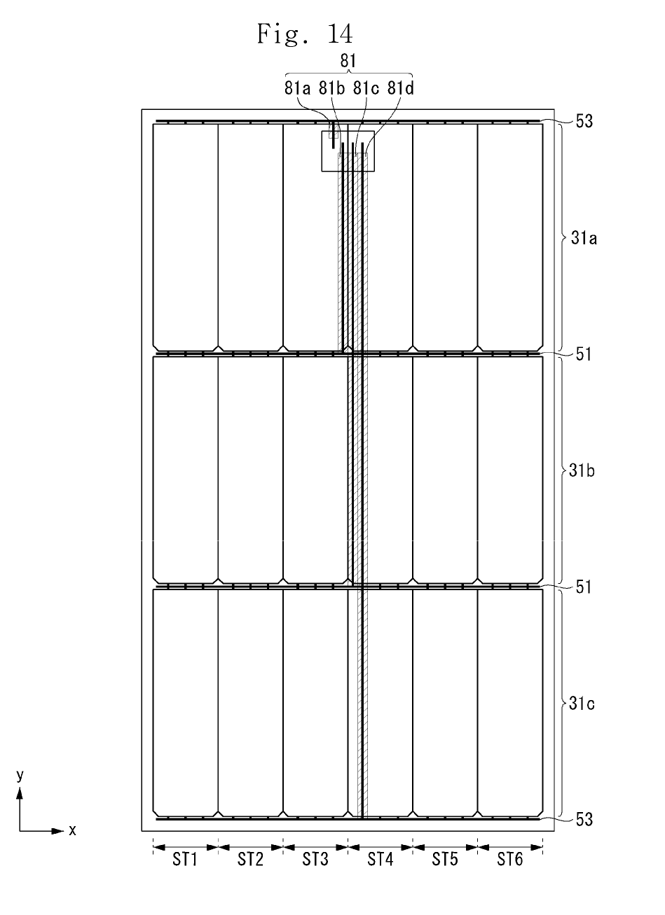

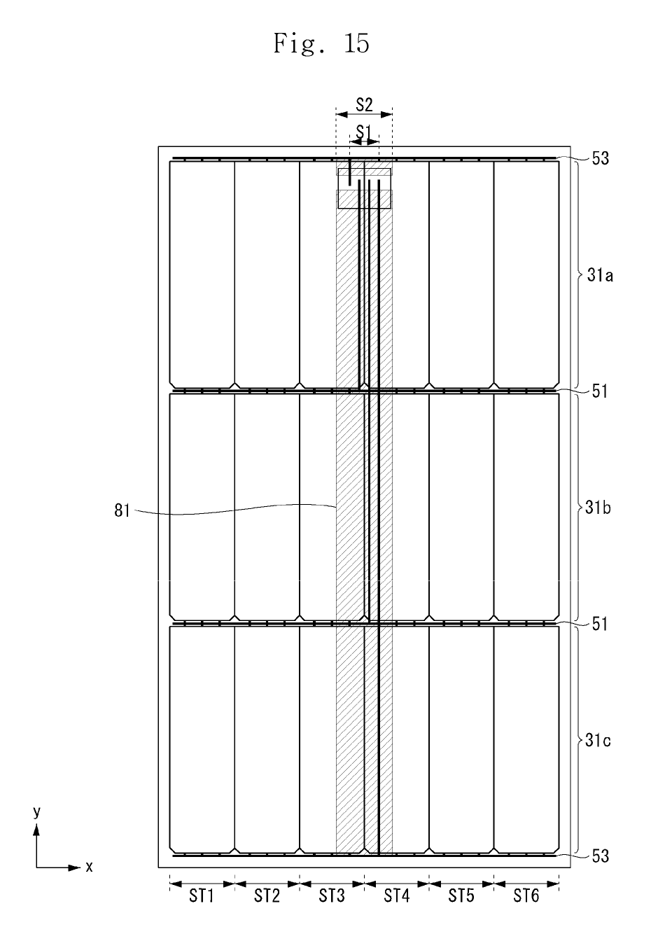

An insulating member 81 is further disposed between the first to fourth bushing connectors 55a to 55d and the rear surface of the string so that the first to fourth bushing connectors 55a to 55d prevent the string from being electrically connected (See FIGS. 14 and 15).

In a preferred example, the insulation member 81 has a width S2 greater than the width S1 between the first bushing connector 55a and the fourth bushing connector 55d, and the length of the string y axis direction), and the insulating member 81 may be formed into a single sheet for convenience of operation.

Alternatively, the insulating member 81 may be provided separately for each of the first to fourth bushing connectors 55a to 55d. In this case, the insulating member may include the first to fourth insulating members 81a to 81d so that the insulating member may be disposed for each of the bushing connectors 55a to 55d. If the insulating member 81 is disposed for each bushing connector, it is not necessary to replace all of the insulating member or the bushing connector when the insulating member or the bushing connector is damaged.

The insulating member 81 is configured to include various well-known insulating materials (for example, resin), and may be formed in various forms such as films, sheets, and the like.

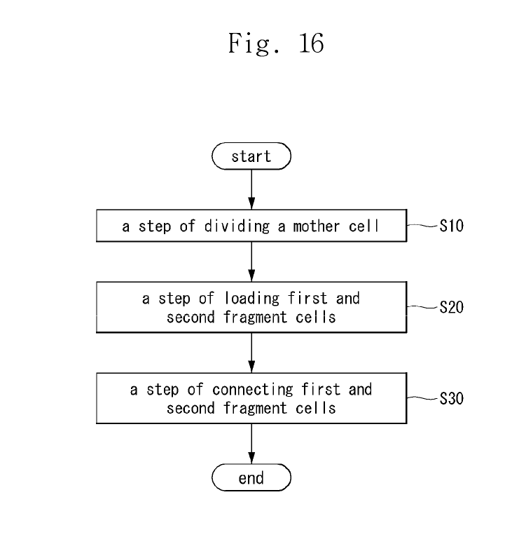

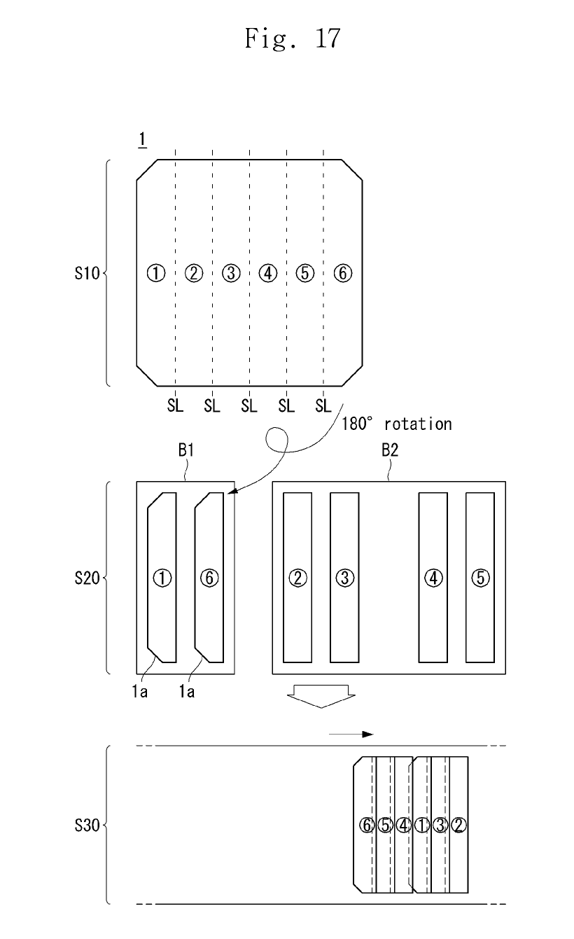

Hereinafter, with reference to FIGS. 16 and 17, a method of forming a solar cell module according to an embodiment of the present invention will be described.

FIG. 16 illustrates a method of manufacturing a solar cell module according to one embodiment of the present invention. FIG. 17 is a schematic view showing a manufacturing method according to one embodiment of the present invention.

Referring to FIGS. 16 and 17, a manufacturing method according to an embodiment of the present invention includes a step of dividing a mother cell S10, a step of loading fragment cells S20, and a step of connecting the fragment cells S30.

The step S10 of dividing the mother cell 1 is a step of dividing the mother cell into a plurality of pieces according to the scribe line SL and the mother cell 1 is divided by various well-known methods, in one example, laser scribing or mechanical scribing.

As the mother cell 1, a mass product having the electrode portion as described above can be used.

The laser is preferably irradiated on the opposite surface of the light receiving surface of the mother cell 1 which receives light. In the case of irradiating the laser to the mother cell 1, the surface of the solar cell is melted by the laser, and a groove is formed while cooling. At this time, heat energy is also applied to the periphery of the groove due to the high heat of the laser, so that the recombination site explosively increases due to the breakage of the bond between the silicon (Si) that has been stabilized. Therefore, when the laser is irradiated on the solar cell, it is preferable that the laser beam is irradiated on the opposite surface of the light receiving surface of the mother cell.

The laser is preferably irradiated on the opposite surface of the light receiving surface of the mother cell 1 which receives light. In the case of irradiating the laser to the mother cell 1, the surface of the solar cell is melted by the laser, and a groove is formed while cooling. At this time, heat energy is also applied to the periphery of the groove due to the high heat of the laser, so that the recombination site explosively increases due to the breakage of the bonding between the silicon (Si) that has been stabilized. Therefore, when the laser is irradiated on the solar cell, it is preferable that the laser beam is irradiated on the opposite surface of the light receiving surface of the mother cell.

For example, as shown in FIG. 4, in a solar cell having a structure in which an emitter is formed on the front surface of a semiconductor substrate and electrodes are formed on the front and rear surfaces of the solar cell, a laser can be irradiated to the rear surface of the solar cell.

Thus, the laser is irradiated to a position outside the pn junction where the carrier is produced, thereby preventing the power generation efficiency of the solar cell from being reduced.

A pulse type laser can be used in a preferred example to reduce the damage. Pulse type laser irradiates a laser in synchronization with pulses, so pulse type laser are irradiated intermittently, not continuously, while the laser is scanning the mother cell. Therefore, pulse type lasers can reduce the thermal damage to the solar cell than a linear laser in which the laser is continuously irradiated. Preferably, the laser is irradiated several times more than one time to reduce the intensity, and the number of times of irradiation can be adjusted in consideration of the intensity of the laser, the depth of the groove, and the like. According to this, laser can be irradiated by reducing the intensity of the laser, so that the damage to the solar cell can be effectively reduced in the process of dividing the mother cell.

In step S10, the depth of the groove is preferably 51% to 70% of the thickness of the mother cell 1 in a preferred example. After forming the grooves on the surface of the mother cell 1, the mother cell 1 receives a physical force from the outside and is divided into a plurality of fragment cells. However, if the groove depth is less than 51%, the mother cell cannot break along the groove, and cracks and other defects may occur. If the depth of the grooves is 70% or more, the thermal stress transmitted to the mother cell 1 is too large, and the efficiency of the fragments cells drops sharply.

Next, the step S20 of loading the fragment cells is a process of classifying the fragment cells (\textcircled{1}˜\textcircled{6}) made in the step S10 into the different baskets B1 to B2 according to the kind. The fragment cells (\textcircled{1}˜\textcircled{6}) made in the previous step can be divided into the first and second basket (B1, B2) by a robot that moves the fragment cells according to a programmed procedure. Here, the second fragment cell 12 having a chamfer is loaded as the first basket B1, and the fragment cell 11 having a rectangular shape is loaded as the second basket B2. The first fragment cell 11 and the second fragment cell 12 can be easily distinguished from vision inspection by the presence or absence of the chamfer 1a, and can be divided into the first and second basket.

A robot has includes a joint part for moving a fragment cell and a loading part for vacuum-engaging a fragment cell, and an vision part for recognizing the shape of the fragment cell with an image acquired from a camera or a laser. The robots can be used for various types of mechanical configurations and vision methods known to those skilled in the art, such as movement of fragment cells and inspection of shapes.

In this step S20, the robot recognizes the first fragment cell (\textcircled{1}) divided in the mother cell 1 as the second fragment cell 12 based on the acquired image from the vision part, loads it into the first basket B1, and the robot recognizes the second and third fragment cells (\textcircled{2}, \textcircled{3}) is recognized as the first cell 11 and loaded into the second basket B2. And then, the robot recognizes the fourth and fifth fragment cells (\textcircled{4}, \textcircled{5}) as the first fragment cell 11 and loads the fourth and fifth fragment cells (\textcircled{4}, \textcircled{5}) into the second basket B2. Finally, the robot recognizes the sixth fragment cell (\textcircled{6}) as the second fragment cell 12, and the sixth fragment cell (\textcircled{6}) is loaded into the first basket (B1) such that the direction of the chamfer 1a of the sixth fragment cell (\textcircled{6}) is equal to the first fragment cell (\textcircled{1}). For example, the sixth slice cell (\textcircled{6}) is rotated 180° and then loaded into the first basket (B1).

In one preferred embodiment of the present invention, the fragment cells constitute a cell unit 33, which comprises two first fragment cells 11 and one second fragment cell 12. The shape of the cell unit 33 has the same shape as the second fragment cell in one example. However, in this step S20, the second fragment cell is loaded only to the first basket, the first fragment cell is loaded only to the second basket B2. At this time, the first fragment cell loaded in the second basket is loaded so that the chamfer directions are all the same. Therefore, even if a string is formed by mixing first and second fragment cells having different shapes, the fragment cells can be easily separated and the cell unit 33 can be formed by simplifying the working process.

Next, in the step S30 of sequentially connecting the classified fragment cells, the robot sequentially unloads the fragment cells in the first and second baskets B1 and B2 and loads the fragment cells in the device 300 to connect the fragment cells in a shingled manner

First, the robot unloads a second fragment cell (\textcircled{2}) from the second basket B2 and loads the second fragment cell (\textcircled{2}) on the assembling apparatus 30. Next, the robot unloads the third fragment cell (\textcircled{3}) from the second basket B2, and then loads the third fragment cell (\textcircled{3}) so as to partially overlap with the second fragment cell in the assembling apparatus 30. At this time, the overlapping portion of the second fragment cell (\textcircled{2}) with the third fragment cell (\textcircled{3}) forms the overlap portion, and the conductive member (CA) may be provided to the overlap portion before the placement.

Next, the robot unloads the first fragment cell (\textcircled{1}) from the first basket (B1), and then moves the first fragment cell (\textcircled{1}) to the assembling device 30 so as to form the overlapping region with the second fragment cell (\textcircled{2}).

In this step S30, the robot is operated to move the unloaded fragment cell to a simply programmed position, and the direction of the fragment cell is kept unchanged.

As a result, since the robot loads and unloads the fragment cells only in the order and direction in the basket, the movement of the robot can be controlled by a simplified procedure. Therefore, the robot easily prevents malfunctioning of the fragment cells due to malfunction.

In another example method of manufacturing a solar cell module, in step S10 of dividing the mother cell 1, the mother cell 1 may be divided into two pieces of cells that are cut along the center and have the same shape. Then, in the step S20 of classifying the fragment cells, any one of the two fragment cells divided in the mother cell 1 is loaded into the basket, and then the remaining fragment cell is loaded, The chamfers are equally loaded in the basket in the same direction. And, in the step S30 of connecting the sorted fragment cells in order, the fragment cells may be unloaded in the direction in which they are loaded in the basket, and may be supplied to the assembling apparatus to shingle-connect the fragment cells so that the chamfer faces only one direction.

Although embodiments have been described with reference to a number of illustrative embodiments thereof, it should be understood that numerous other modifications and embodiments can be devised by those skilled in the art that will fall within the scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A solar cell module comprising:
an octagonal-shaped semiconductor substrate having a chamfer formed at each edge among at least two opposite edges of the octagonal-shaped semiconductor; and
a first electrode unit formed on one surface of the octagonal-shaped semiconductor substrate, the first electrode unit including:
a plurality of first sub-electrodes including first finger electrodes and a first bus bar electrode connected to ends of the first finger electrodes, and
a plurality of second sub-electrodes including second finger electrodes and a second bus bar electrode connected to ends of the second finger electrodes,
wherein the plurality of first sub-electrodes are spaced apart from the plurality of second sub-electrodes in a first direction, and
wherein a first sub-electrode disposed adjacent to a chamfer at a first edge among the at least two opposite edges in the first direction among the plurality of first sub-electrodes, and a second sub-electrode disposed adjacent to another chamfer at a second edge among the at least two opposite edges are symmetrical in a longitudinal direction of the first and second bus bar electrodes.

2. The solar cell of claim 1, wherein the first bus bar electrode and the second bus electrode connect to opposite sides of the corresponding finger electrodes among the first and second finger electrodes.

3. The solar cell of claim 2, wherein a plurality of third sub-electrodes including third finger electrodes connected to a third bus bar are disposed between the plurality of first sub-electrodes and the plurality of second sub-electrodes.

4. The solar cell of claim 3, wherein the third bus bar electrode and the second bus electrode connect to opposite sides of the corresponding finger electrodes among the third and second finger electrodes, and the third bus bar electrode and the plurality of third sub-electrodes have a similar connection relationship as the first bus bar electrode and the plurality of first sub-electrodes.

5. The solar cell of claim 1, wherein the first and second bus bar electrodes each have a line shape and a line width greater than a line width of each of the first and second finger electrodes.

6. The solar cell of claim 1, wherein the first electrode unit is disposed on a rear surface of the octagonal-shaped semiconductor substrate.

7. A solar cell module comprising:
a string of cell blocks, each of the cell blocks including a plurality of cell units connected to each other, each of the plurality of cell units including a plurality of fragment cells connected in a shingled manner; and
a connector connecting between two adjacent cell blocks among the cell blocks,
wherein each of the plurality of cell units includes a first fragment cell type having a long side and a short side and a second fragment cell type having a chamfer at an edge of the second fragment cell.

8. The solar cell module of claim 7, wherein the plurality of fragment cells connected in the shingled manner form a zig-zag pattern from a side view.

9. The solar cell module of claim 7, wherein each of the plurality of cell units includes two fragment cells of the first fragment cell type and one fragment cell of the second fragment cell type.

10. The solar cell module of claim 7, wherein each of the cell blocks has seven cell units, and the string includes three cell blocks.

11. The solar cell module of claim 10, wherein the string includes a plurality of strings having the cell blocks, the plurality of strings being connected to each other in parallel,
wherein each of the plurality of strings includes a connector connecting between two adjacent cell blocks within the corresponding string, and
wherein the connector in each of the plurality of strings are electrically connected to each other by a first inter-connecter arranged to intersect the connector in each of the plurality of strings.

12. The solar cell module of claim 10, wherein the connecter in each of the plurality of strings is located approximately at a center of the corresponding string for dispersing a stress to the corresponding string.

13. The solar cell module of claim 11, further comprising an edge connector connected to at least one end of each of the plurality of strings,
wherein the edge connector in each of the plurality of strings are electrically connected to each other by a second inter-connecter disposed parallel to the first inter connecter.

14. The solar cell module of claim 13, wherein the connector, the first inter-connecter, the second inter-connecter, and the edge connector in each of the plurality of strings are ribbons, each of the ribbons includes a conductor and solder covering the conductor.

15. The solar cell module of claim 13, further comprising:
a junction box disposed at a rear surface of the string and having a bypass diode therein,
a first bushing connector for connecting the bypass diode and the first inter-connecter in a direction crossing the first inter-connecter, and
a second bushing connector disposed in parallel with the first inter-connector and connecting the second inter-connector to the bypass diode.

16. The solar cell module of claim 15, further comprising:
an insulating member disposed between a rear surface of the string and the first and second bushing connectors,
wherein the insulating member is disposed separately for each of the first and second bushing connectors.

17. The solar cell module of claim 7, wherein each of the first and second fragment cell types include a plurality of finger electrodes on one side and a bus bar electrode connected to one side of the plurality of finger electrodes,
wherein the bus bar electrode in each of the first and second fragment cell types is disposed along a long side of the corresponding cell fragment, and
wherein the bus bar electrode in the second fragment cell type is disposed closer to an edge that is located opposite to an edge having the chamfer.

18. The solar cell module of claim 17, wherein the connector includes a pair of first portions spaced apart from each and arranged in parallel to each other, and a plurality of second portions connecting the pair first portions to each other, and
wherein one first portion among the pair of first portions is facing and connected to the bus bar electrode of a first cell block arranged adjacent to an edge of the cell block.

19. A method for manufacturing a solar cell module, the method comprising:
dividing a solar cell into a first fragment cell having a rectangular shape and a second fragment cell having a chamfer, the solar cell including an octagonal-shaped semiconductor substrate having a chamfer formed at an edge, a first electrode unit formed on one surface of the octagonal-shaped semiconductor substrate and having a plurality of sub-electrodes including finger electrodes and a bus bar electrode connected to ends of the finger electrodes, wherein the plurality of sub-electrodes are spaced apart from neighboring sub-electrodes in a first direction, and include a first sub-electrode disposed adjacent to a chamfer in the first direction at one edge of the solar cell among the plurality of sub-electrodes and a second sub-electrode disposed adjacent to another chamfer at another edge of the solar cell;
loading the first fragment cell having the rectangular shape into a first basket;
loading the second fragment cell having the chamfer into a second basket; and
connecting the first fragment cell to the second fragment cell by unloading the first fragment cell and the second fragment cell from the first and the second baskets, and then positioning the second fragment cell to partially overlap the first cell fragment,
wherein the dividing the solar cell includes dividing the solar cell into a plurality of fragment cells aligned with scribe lines disposed between the plurality of sub-electrodes,
wherein the first sub-electrode and the second sub-electrode are symmetrical in a longitudinal direction of the bus bar electrode, and
wherein the loading the second fragment cell includes the second fragment cell being loaded in the second basket with the chamfer being oriented in a same direction as another previously loaded second fragment cell.

20. The method of claim 19, wherein a number of first fragment cells loaded in the first basket is at least twice as much as a number of second fragment cells loaded in the second basket.
